(19) United States
(12) Patent Application Publication
(10) Pub. No.: US 2014/0153207 A1
(43) Pub. Date: Jun. 5, 2014

(54) CIRCUIT BOARD MOUNTING APPARATUS

(71) Applicant: HON HAI PRECISION INDUSTRY CO., LTD., New Taipei (TW)

(72) Inventors: CHIEN-CHUNG HUANG, New Taipei (TW); ZHENG-HENG SUN, New Taipei (TW)

(73) Assignee: HON HAI PRECISION INDUSTRY CO., LTD., New Taipei (TW)

(21) Appl. No.: 13/727,530

(22) Filed: Dec. 26, 2012

(30) Foreign Application Priority Data
Dec. 4, 2012 (CN) 201210512029.9

(51) Int. Cl. H05K 7/14

(52) U.S. Cl. CPC H05K 7/14
USPC 361/767

(57) ABSTRACT

A circuit board mounting apparatus includes a chassis and a circuit board. The chassis includes a side plate defining a slide slot and a latching hole. A latch protrudes forward from the circuit board, and includes a neck and a latching portion extending left from a front end of the neck. A cutout is defined in a front side of the circuit board. A cantilever extends into the cutout. A hook protrudes forward from the cantilever. The latch extends through the slide slot to allow the neck to abut against a portion of the side plate bounding a left end of the slide slot, and to allow the latching portion to engage with a front side of the side plate. The cantilever resists the hook to engage in the latching hole and abut against a portion of the side plate bounding a right end of the latching hole.

### BACKGROUND

1. Technical Field

The present disclosure relates to a circuit board mounting apparatus.

2. Description of Related Art

In electronic devices, circuit boards may be mounted inside the devices with a number of screws extended through the circuit board and engaged in a number of posts on a bottom plate of the chassis of the devices. However, fastening screws manually in the chassis can be difficult and inconvenient because of limited space for maneuvering.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a circuit board mounting apparatus.

FIG. 2 is a partially assembled, isometric view of FIG. 1.

FIG. 3 is an assembled, isometric view of FIG. 1.

FIG. 4 is similar to FIG. 3, but viewed from another perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”.

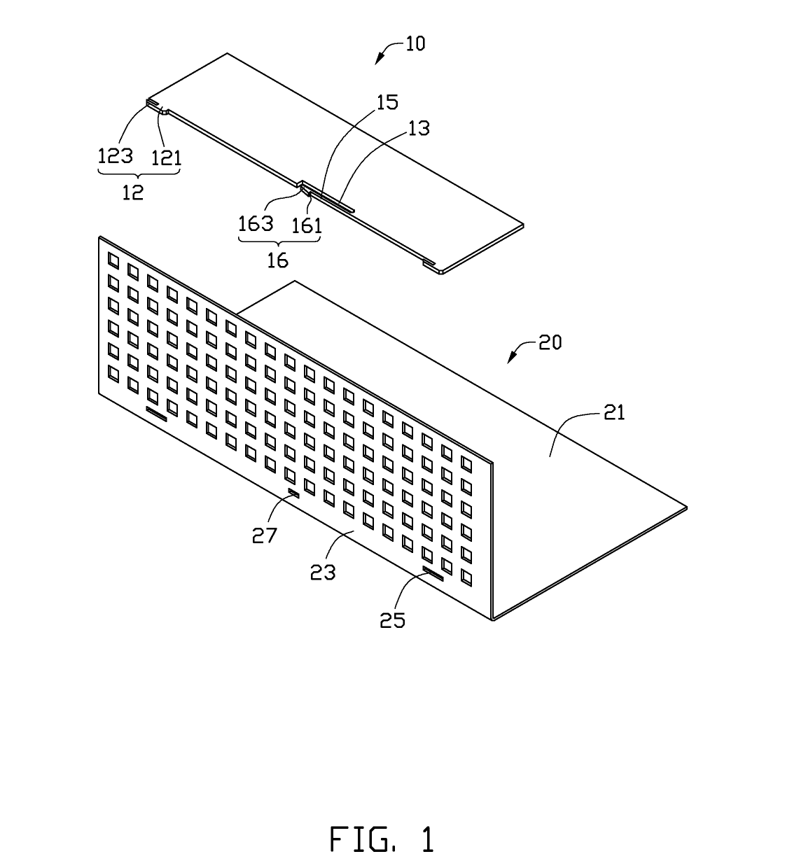

FIG. 1 shows an exemplary embodiment of a circuit board mounting apparatus. The circuit board mounting apparatus includes a circuit board 10 and a chassis 20.

Two substantially L-shaped latches 12 protrude from a front side of the circuit board 10. Each latch 12 includes a neck 121 connected to the front side of the circuit board 10, and a latching portion 123 extending left from the front end of the neck 121. A cutout 13 is defined in the front side of the circuit board 10, between the latches 12. A cantilever 15 horizontally extends left from a right end wall bounding the cutout 13. The cantilever 15 is received in the cutout 13. A hook 16 protrudes forward from a distal end of the front side of the cantilever 15. The hook 16 includes an engaging surface 161 facing rightward and perpendicular to the cantilever 15, and a guide surface 163 facing leftward and slantingly connected between the cantilever 15 and the front end of the engaging surface 161.

The chassis 20 includes a bottom plate 21 and a side plate 23 extending up from the front side of the bottom plate 21 in a substantially perpendicular manner Two horizontally extending slide slots 25 are defined in the side plate 23, adjacent to the bottom plate 21. A latching hole 27 is defined in the side plate 23, between the slide slots 25.

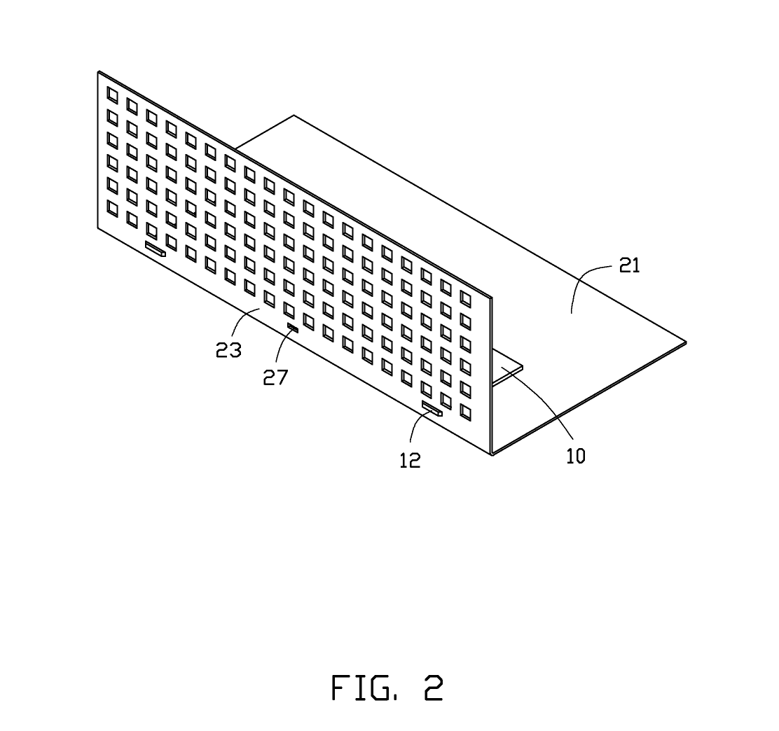

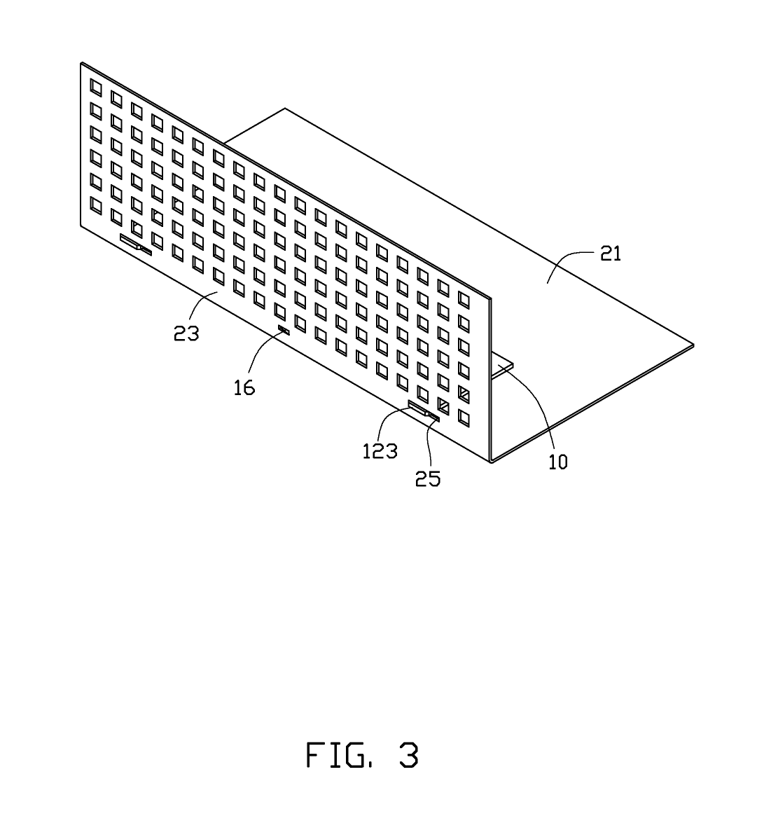

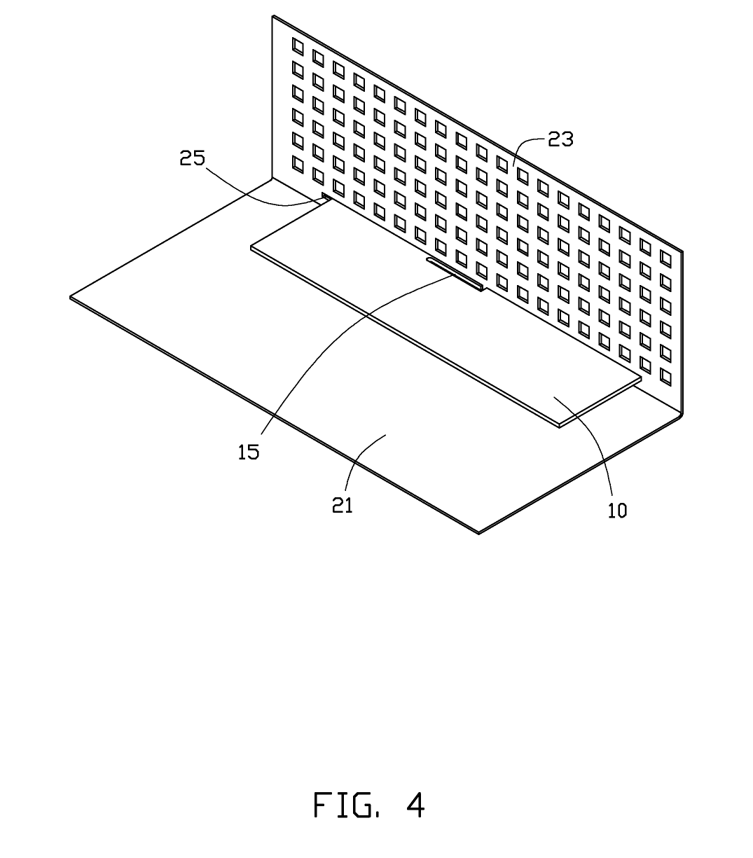

FIGS. 2 to 4 show that in assembly, the circuit board 10 is placed in the chassis 20, parallel to the bottom plate 21. The latches 12 are respectively extended through the slide slots 25, to allow the front side of the circuit board 10 to abut the rear side of the side plate 23. The guide surface 163 of the hook 16 abuts against the rear side of the side plate 23 and reversely deforms the cantilever 15. The circuit board 10 is slid left along the side plate 23, until the necks 121 abut against portions of the side plate 23 bounding the left ends of the slide slots 25. The latching portions 123 abut the front side of the side plate 23. The hook 16 aligns with the latching hole 27. The cantilever 15 is restored to engage the hook 16 in the latching hole 27, to allow the engaging surface 161 to abut against a portion of the side plate 23 bounding the right end of the latching hole 27. Thereby, the circuit board 10 is perpendicularly mounted to the side plate 23.

In the embodiment, the circuit board 10 is mounted to the chassis 20 without screws, which is convenient.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A circuit board mounting apparatus, comprising:
a chassis comprising a side plate defining a latching hole and at least one slide slot; and
a circuit board, at least one substantially L-shaped latch protruding from a front side of the circuit board, each of the at least one latch comprising a neck connected to the front side of the circuit board, and a latching portion extending left from a front end of the neck, the front side of the circuit board defining a cutout, a cantilever extending from an end wall bounding the cutout, a hook protruding from a front side of the cantilever and comprising an engaging surface facing rightward;
wherein the at least one latch extends through the at least one slide slot and slides to allow the neck to abut against a portion of the side plate bounding a left end of the slide slot, and to allow the latching portion to engage with a front side of the side plate, the cantilever resists the hook to engage in the latching hole, to allow the engaging surface of the hook to abut against a portion of the side plate bounding a right end of the latching hole, to perpendicularly fix the circuit board to the side plate.

2. The circuit board mounting apparatus of claim 1, wherein the cantilever is received in the cutout, and extends horizontally from the end wall bounding the cutout.

3. The circuit board mounting apparatus of claim 2, wherein the hook protrudes from a distal end of the front side of the cantilever.

4. The circuit board mounting apparatus of claim 3, wherein the cantilever extends left from a right end wall bounding the cutout.

5. The circuit board mounting apparatus of claim 1, wherein the number of the at least one slide slot is two, and the number of the at least one latch is two, the latching hole is arranged between the two slide slots, and the cantilever is arranged between the two latches.

6. The circuit board mounting apparatus of claim 1, wherein the hook further comprises a guide surface facing leftward and slantingly connected between the cantilever and the front end of the engaging surface.

7. The circuit board mounting apparatus of claim 1, wherein the front side of the circuit board abuts against a rear side of the side plate.
